(19) United States
(12) Patent Application Publication
(10) Pub. No.: US 2011/0163765 A1
(43) Pub. Date: Jul. 7, 2011

(54) CAPACITIVE OCCUPANT DETECTION SYSTEM HAVING WET SEAT COMPENSATION AND METHOD

(76) Inventors: Charles A. Gray, Noblesville, IN (US); Kevin D. Kincaid, Kokomo, IN (US); Kevin R. Starich, Kokomo, IN (US); Robert K. Constable, Kokomo, IN (US); Mark C. Hansen, Kokomo, IN (US)

(21) Appl. No.: 12/683,836

(22) Filed: Jan. 7, 2010

(51) Int. Cl. G01R 27/26; G06F 19/00

(52) U.S. Cl. 324/665; 324/658; 702/65; 702/65

(57) ABSTRACT

An occupant detection system and method are provided. The system includes a capacitive sensor having an electrode arranged in a seat proximate to an expected location of an occupant for sensing an occupant presence approximate thereto. The capacitive sensor is configured to provide an output indicative of the sensed occupant presence. Occupant detection circuitry is included for processing the capacitive sensor output and determining a wet seat condition and generating a wet seat fault based on a determined wet seat condition. The occupant detection circuitry further detects a state of occupancy of the seat based on the capacitive sensor output and the wet seat fault.

### TECHNICAL FIELD

The present invention generally relates to occupant sensing systems, and more particularly relates to a system and method for detecting an occupant on a vehicle seat that includes an electrode configured to generate a capacitance that is dependent on presence of an occupant.

### BACKGROUND OF THE INVENTION

Automotive vehicles are commonly equipped with air bags and other devices that are selectively enabled or disabled based upon a determination of the presence of an occupant in a vehicle seat. It has been proposed to place electrically conductive material in a vehicle seat to serve as an electrode for detecting the presence of an occupant in the seat. For example, U.S. Patent Application Publication No. 2009/0267622 A1, which is hereby incorporated herein by reference, describes an occupant detector for a vehicle seat assembly that includes an occupant sensing circuit that measures the impedance of an electric field generated by applying an electric signal to the electrode in the seat. The presence of an occupant affects the electric field impedance, particularly the load capacitance about the electrode that is measured by the occupant sensing circuit.

When the vehicle seat gets wet from liquid exposure such as from rain or spilled liquids, the electrical resistance of the seat typically changes significantly which, in turn, amplifies the difference between the transmitted and received signal amplitude. The occupant detection system generally may detect moisture in the seat and generate a wet set fault which may be used to illuminate a warning lamp to warn the passenger that the system is unable to operate properly due to the presence of liquid in the seat.

It would be desirable to provide for accurate sensing of occupancy of a seat using an electrode configured to sense capacitance of a load in a manner that effectively handles the wet seat scenario.

### SUMMARY OF THE INVENTION

According to one aspect of the present invention, an occupant detection system is provided. The system includes a capacitive sensor comprising an electrode arranged in a seat proximate to an expected location of an occupant for sensing an occupant presence proximate thereto. The capacitive sensor is configured to provide an output indicative of the sensed occupant presence. The system further includes occupant detection circuitry for processing the capacitive sensor output and determining a wet seat condition and generating a wet seat fault based on a determined wet seat condition. The occupant detection circuitry further detects a state of occupancy of the seat based on the capacitive sensor output and the wet seat fault.

According to another aspect of the present invention, a method of detecting an occupant in a seat is provided. The method includes the steps of applying an alternating current signal to an electrode arranged in a seat proximate to an expected location of an occupant for generating an electric field at the expected location, detecting a voltage response to the electric field, and generating an output based on the voltage response indicative of a characteristic of an occupant. The method also includes the steps of detecting a wet seat condition, and generating a wet seat fault based on the detected wet seat condition. The method further includes detecting a state of occupancy of the seat based on the output and the wet seat fault.

These and other features, advantages and objects of the present invention will be further understood and appreciated by those skilled in the art by reference to the following specification, claims and appended drawings.

### BRIEF DESCRIPTION OF THE DRAWINGS

The present invention will now be described, by way of example, with reference to the accompanying drawings, in which:

FIG. 1 is a partial exploded perspective view of a seat assembly incorporating an occupant detection system, according to one embodiment;

FIG. 2 is a block/circuit diagram of the occupant detection system, according to one embodiment;

FIG. 3 is a circuit diagram modeling the sensed characteristics of a load with the occupant detection system, according to one embodiment;

FIGS. 4A and 4B is a flow diagram illustrating a routine for sensing occupancy of a seat based on capacitive sensing;

FIG. 5 is a flow diagram for classifying an occupant based on the capacitive sensing;

FIG. 6 is a flow diagram illustrating a routine for performing wet seat fault setting updates, according to one embodiment; and

FIG. 7 is a flow diagram illustrating a routine for performing wet seat fault clearing adjustments, according to one embodiment.

### DESCRIPTION OF THE PREFERRED EMBODIMENTS

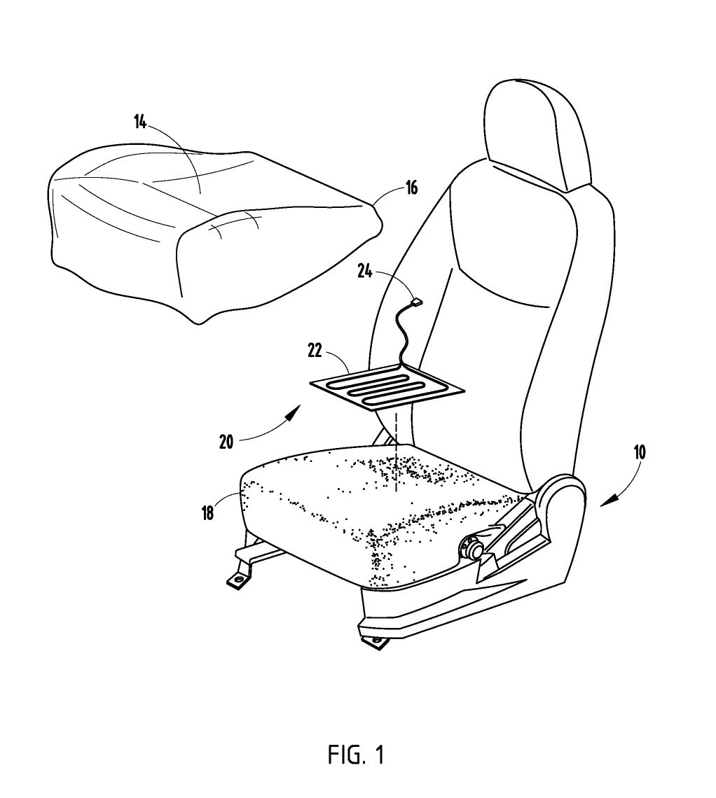

Referring now to FIG. 1, an exemplary automotive vehicle seat assembly 10 is generally shown having a top side seating surface 14 suitable for supporting an occupant (not shown). The seat assembly 10 is adapted to be installed in a vehicle passenger compartment, such as a car seat, according to one embodiment, but could be used in any kind of vehicle, such as an airplane, according to another embodiment. The seat assembly 10 has a foam cushion 18 and an overlaying outer covering 16, and a capacitive sensing electrode 22 installed in the seat assembly 10 on or proximate to the top side seating surface 14. In the embodiment shown, the electrode 22 may be installed on top of the foam cushion 18 and below the outer trim covering 16 which is generally referred to as the A-surface of the cushion foam. The electrode 22 effectively serves as an antenna or capacitive sensor to detect occupancy of the seat 10. The electrode 22 may be formed of suitable materials that allow for electrical conductivity for the electrode 22 to receive a signal and generate a voltage output that may include metal wire, conductive fiber, metal foil, metal ribbon, conductive ink and other conductive materials formed in the shape of a mat or other shape. The vehicle seat assembly 10 includes an occupant detection system 20 which utilizes the capacitive based electrode 22 for sensing occupancy of the seat assembly 10. The occupant detection system 20 further compensates for wet conditions of the seat such as that caused by liquid or high humidity to provide for accurate sensing of an occupant, despite the presence of liquid on or in the seat assembly 10.

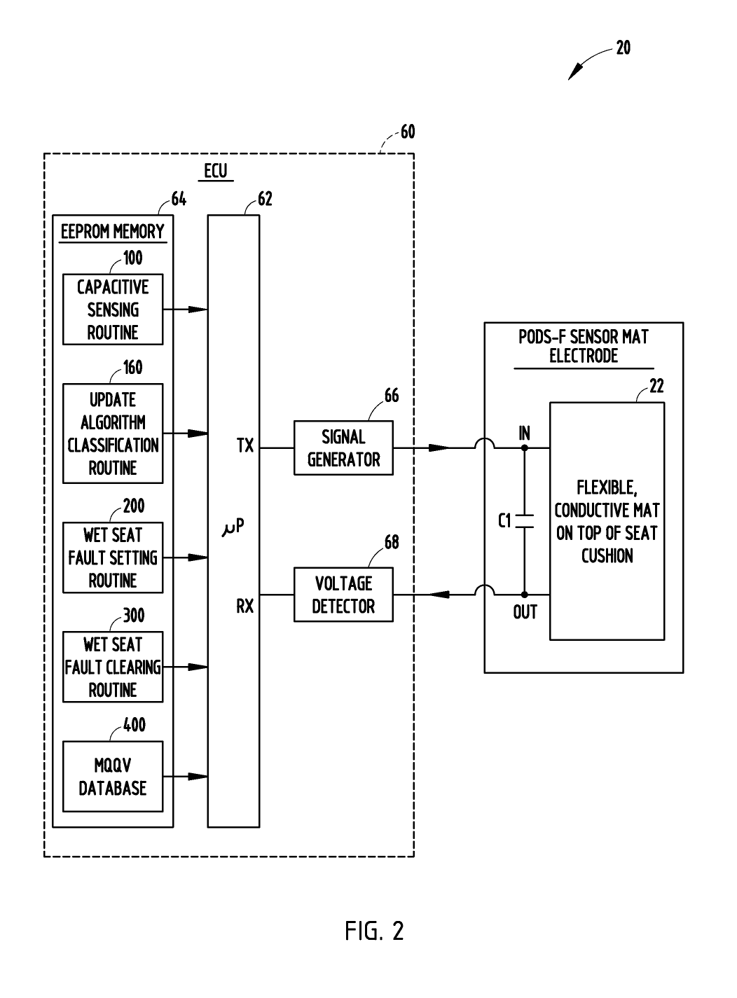

The occupant detection system 20 is illustrated in FIG. 2, according to one embodiment. The occupant detection system 20 includes occupant detection circuitry shown implemented as an electronic control unit (ECU) 60 in communication with the capacitive based electrode 22. The ECU 60 is shown including a microprocessor 62 and memory 64. Memory 64 may include electrically erasable programmable read-only memory (EEPROM) or other volatile and/or non-volatile memory. Stored in memory 64 is a capacitive sensing routine 100, an update algorithm classification routine 160, a wet seat fault setting compensation routine 200 and a wet seat fault clearing compensation routine 300. Memory 64 also stores various data values including wet seat fault thresholds in database 400. The routines 100, 160, 200 and 300 may be executed by the microprocessor 62. It should be appreciated that other control circuitry may be employed to process the various routines, acquire the data, and provide wet seat fault compensation and occupant detection outputs as described herein.

The ECU 60 is also shown having a signal generator 66 and a voltage detector 68. The signal generator 66 is configured to output a plurality of alternating current (AC) signals at different frequencies. This may include generating a first sine wave signal at a first frequency during a first time period and a second sine wave signal at a second frequency during a second time period. A total of n AC signals at n frequencies may be generated. The plurality of n signals may be output simultaneously or sequentially by the signal generator 66 and applied to the electrode 22 to generate an electric field proximate to the top side seat surface 14.

The signal generator 66 is configured to generate an electric field projected to a location at which an object (occupant) is to be detected, such as the top side seating surface 14 of the seat assembly 10. The impedance of a load affects the voltage response received by the voltage detector 68. The voltage detector 68 measures a voltage for each of the n frequencies at the n time periods. The measured voltages may depend upon the impedance of the load which may include impedance caused by an occupant and environmental conditions such as humidity, moisture from liquid and temperature.

It should be appreciated that the microprocessor 62 may include a plurality of noise filters (not shown) and may convert the measured voltages into digital voltage amplitudes. The voltage amplitudes may be compared to determine if a change in voltage has occurred amongst the plurality of frequencies. A change or difference in voltages is typically indicative of the presence of an environmental condition that will affect the impedance of a load.

The occupant detection system 20 advantageously processes the capacitive based sensor output and determines occupancy of the vehicle seat. The output of the occupant detection system 20 may be used to enable, disable or change the response of a vehicle air bag system or other vehicle systems. In some applications, deployment of an air bag may be enabled when a person or object of a specific size or shape is seated in the vehicle seat. The size of a person may be proportional to the person's impedance and will affect the voltage sensed by the electrode 22. Additionally, environmental conditions including a wet seat condition may affect the loading on the system, particularly the electrode 22. The electrode 22 may be compensated to actively control the deployment system(s) by compensating for the detected environmental condition(s).

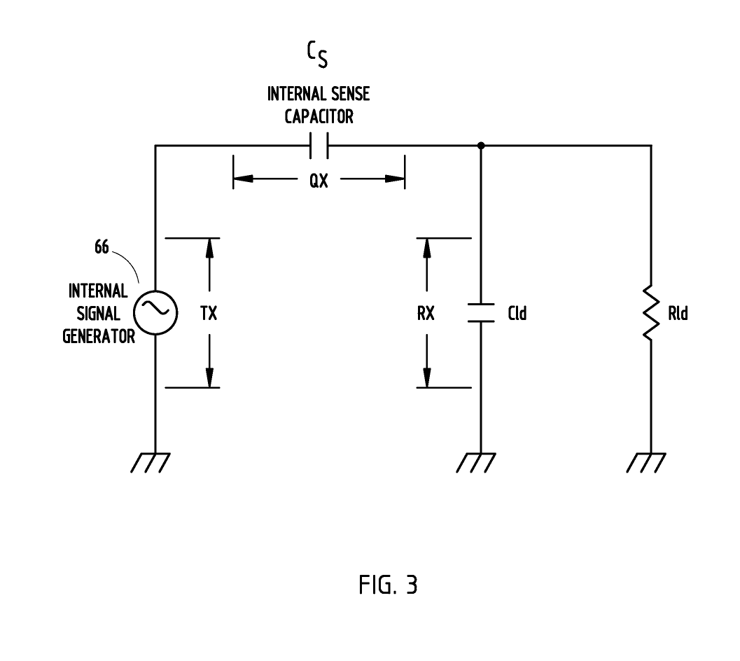

FIG. 3 illustrates a circuit diagram useful for describing a first-order equivalent model of the occupant detection system 20 when operating during a humid/wet condition. The circuit shows the signal generator generating the transmit signal TX and the receive signal RX sensed across the load capacitor Cld which provides a capacitance term. The load also has a resistive term shown by load resistor Rld. Thus, the load has both a capacitance term (Cld) and a resistive term (Rld) which make up the impedance of the load. The occupant detection system 20 also has an internal sense capacitor Csense for sensing the capacitance related value Q_{X}.

The load includes the seat, any occupant and environmental conditions. The load generally acts as a high pass filter with a pole location of 1/(2πR(Cs+Cld)), where Cs is the sensed capacitance. The received signal RX may be represented by the following equation:

$$RX = \frac{Zoccupant}{Zsense + Zoccupant} TX$$

The capacitance related value Q_{X} may be defined by the following equation:

$${Q}_{X} = \frac{Zsense}{Zoccupant} TX$$

The capacitance related value Q_{X} may further be defined by the following equation:

$${Q}_{X} = {T}_{X} * [ \frac{1 + j2π {fR}_{ld} {C}_{ld}}{1 + j2π {fR}_{ld} ( {C}_{ld} + {C}_{s} )} ]$$

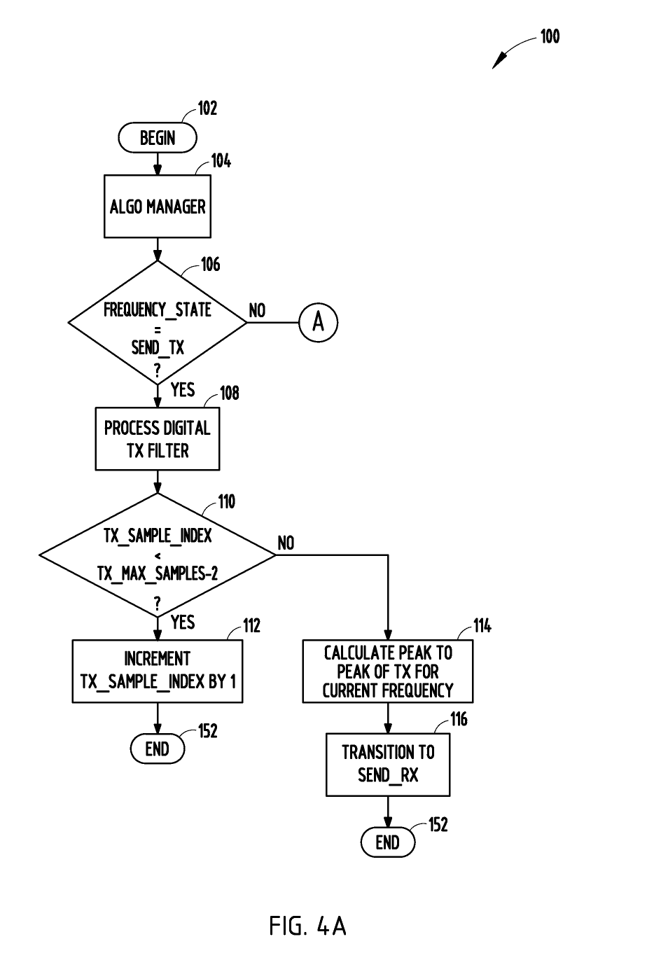

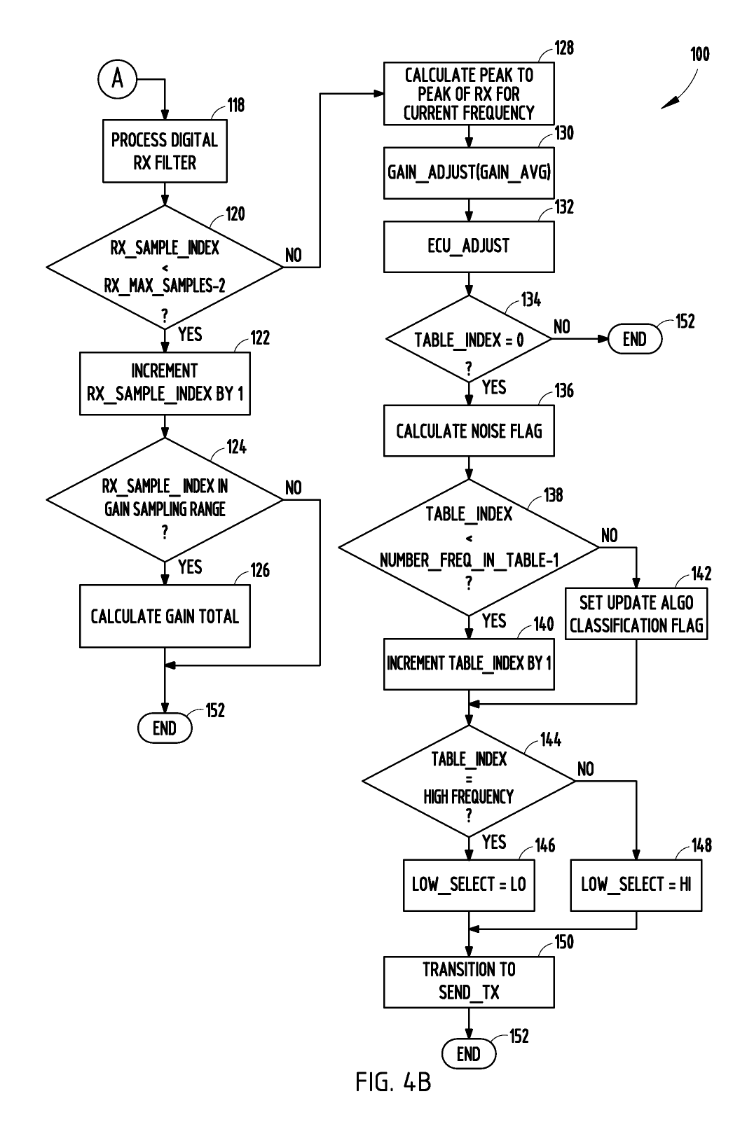

Referring to FIGS. 4A and 4B, a capacitive sensing routine 100 is illustrated according to one embodiment. Routine 100 begins at step 102 and proceeds to step 104 to call the algorithm manager, which may occur at a rate of 120 microseconds, according to one example. Next, at decision step 106, routine 100 determines if the frequency state is set equal to the send TX signal such that the AC transmit signal is being transmitted and, if so, processes the digital transmit filter at step 108. At decision step 110, routine 100 determines if the transmit sample index is less than the maximum transmit samples minus two, such that the requisite number of four frequency signals have completed their transmission. If the transmission of four frequency signals is not complete, routine 100 proceeds to increment the TX_sample index by one in step 112 and ends at step 152. If the transmit signals are done transmitting at the requisite four frequencies, routine 100 proceeds to step 114 to calculate the peak-to-peak amplitude of the transmit signal for the current frequency to get a measurement of the amplitude, and then proceeds to step 116 to transition to the send RX receive signal. Accordingly, routine 100 transmits signals at four separate frequencies. According to one embodiment, three of the frequencies are high frequencies generally in a range near about 100-220 KHz, and the one low frequency signal is generally in a range near about 1 KHz-10 KHz.

Returning back to step 106, if routine 100 determines that the frequency state is not in the transmit mode, routine 100 proceeds to step 118 to process the digital received RX filter. According to one embodiment, the RX filter uses a 1040 tap filter for the low frequency, and a 80 tap filter for the high frequencies. Next, routine 100 proceeds to decision step 120 to determine if the received RX sample_index is less than the received sample maximum minus two so as to determine whether or not RX signals have been received at all four frequencies. If the RX signals have not been received at all four frequencies, routine 100 proceeds to step 122 to increment the RX sample_index by one, and then determines in decision step 124 if the RX sample_index is within the gain sampling range and, if so, calculates a gain total at step 126. Otherwise, routine 100 ends at step 122. If the received signal has been received for all four frequencies, routine 100 proceeds to step 128 to calculate the peak-to-peak amplitude of the received RX signal for the current frequency. Next, at step 130, routine 100 performs a gain adjust to adjust the gain of the amplifier in the waveform generator to keep the average signal amplitude substantially constant. This may be achieved with a feedback loop to compensate for environmental effects, such as humidity. At step 132, routine 100 adjusts the ECU to calculate the Q_{X} raw value, which normalizes for variations in the ECU synthesizer chip, such that the output remains substantially stable. At decision step 134, routine 100 determines if the table index is equal to zero and, if not, ends at step 152. If the table index is set equal to zero, routine 100 proceeds to step 136 to calculate a noise flag and then proceeds to decision step 138 to determine if the table_index is less than the number of frequencies in the table minus one, which essentially checks for noise on each individual frequency signal. If the decision in step 138 is determined to be yes, routine 100 proceeds to step 140 to increment the table_index by one. Otherwise, the update algorithm classification flag is set at step 142. At decision step 144, routine 100 determines if the table_index is equal to the high frequency and, if so, sets the low select to low at step 146 before transitioning to the send TX signal at step 150 and ending at 152. Otherwise, the low select signal is set to high at step 148 before transitioning to the send TX signal at step 150.

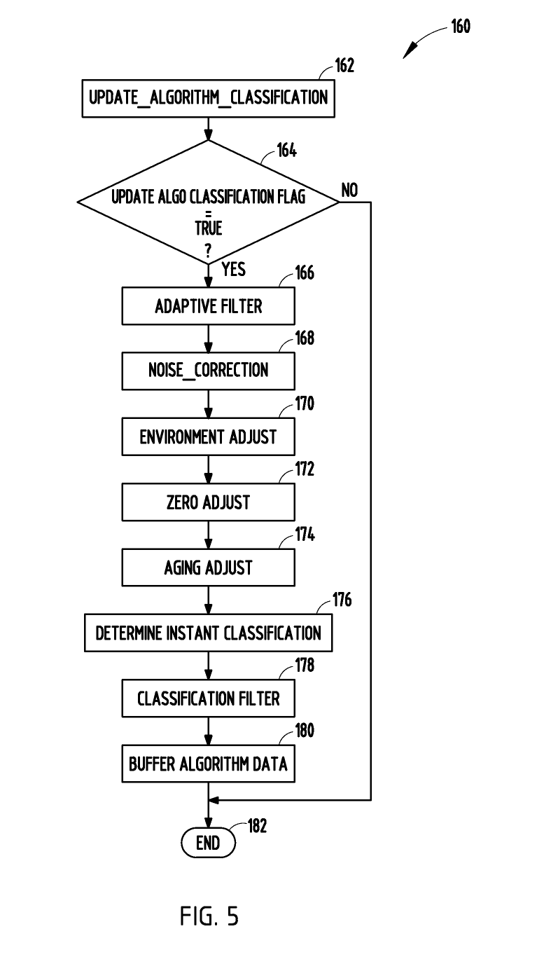

Referring to FIG. 5, an update algorithm classification routine for classifying the capacitive sensed occupant is illustrated as generally indicated by identifier 160. Routine 160 begins the update algorithm classification at step 162, and proceeds to decision step 164 to determine whether the update algorithm classification flag is set equal to true, and if not, ends at step 182. If the update algorithm classification flag is set equal to true (e.g., binary “1”), then routine 160 proceeds to step 166 to perform adaptive filtering and then to step 168 to provide noise correction. Next, routine 160 proceeds to the environmental adjust step 170 to compensate for environmental conditions, such as humidity. Next, a zero adjusts step is performed at step 172 in which the capacitive value for an empty seat may be adjusted so as to normalize the seat setting, which may occur at the vehicle assembly facility, according to the automotive application. At step 174, routine 160 may periodically provide an aging compensation adjust step to adjust for variations in values during aging of the seat over time and usage. At step 176, routine 160 may determine an instant classification which may be achieved by comparing the median Q_{X} value against a threshold value. At step 178, routine 160 may perform a classification filter which may look for a plurality of comparisons to obtain consecutive Q_{X} middle values exceeding a threshold value. It should be appreciated that Q_{X} is the approximate measure of capacitance and that four Q_{X} values may be obtained, corresponding to the three high frequencies and the fourth low frequency. The middle peak-to-peak amplitude value of the three high frequency Q_{X} values may be used to determine whether or not to classify an occupant as an adult. The difference between the low and the high Q_{X} values may be used to adjust for humidity. Q_{X} may be defined in one embodiment by the following equation:

$${Q}_{X} = \frac{{R}_{X} - {T}_{X}}{{T}_{X}} \cdot sensed capacitor value ( C s ) ,$$

wherein Q_{X} is approximately on count per picofarad. At step 180, routine 160 may perform a buffer algorithm to buffer the data, before ending at step 182. Accordingly, it should be appreciated that the routines 100 and 160 advantageously provide for an output signal indicative of an occupant and the classification of the occupant based on the capacitive sensing.

The occupant detection system 20 may advantageously compensate for wet seat conditions of the seat and the sensor by adjusting the wet seat fault threshold, according to one embodiment. The detection system 20 employs the wet seat fault setting compensation routine 200 to periodically update wet seat faults. Additionally, occupant detection system 20 includes a wet seat fault clearing compensation routine 300 to periodically clear and update the wet seat fault settings so as to compensate for wet seat conditions.

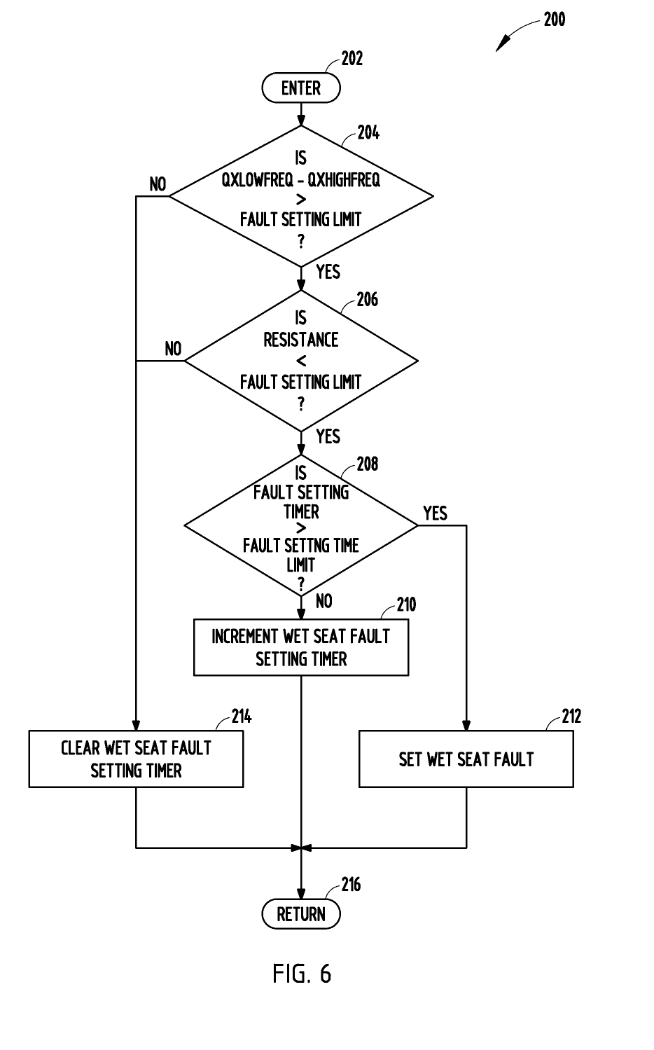

The wet seat fault setting compensation routine 200 is illustrated in FIG. 6, according to one embodiment. Routine 200 begins at step 202 and proceeds to decision step 204 to determine if the difference between the low frequency Q_{X} value (e.g., 2 KHz) Q_{X}LowFreq and the high frequency Q_{X} value (e.g., 287 KHz) Q_{X}HighFreq is greater than a fault setting limit and, if not, proceeds to step 214 to clear the wet seat fault setting timer before returning at step 216. If the difference exceeds the fault setting limit, then routine 200 proceeds to decision step 206 to determine whether the resistance is less than a fault setting limit resistance value. The resistance may be determined by processing the resistive term of the sensed impedance. The resistance may be determined by evaluating the frequency response of a filter formed by the load resistance Rld and load capacitance Cld. This may include driving the filter with the high frequency signal and the low frequency signal, and processing the relative amplitude at the high and low frequency signals to determine the capacitive and resistive terms. If the resistance is not less than the fault setting limit resistance value, the routine 200 proceeds to clear the wet seat fault setting timer at step 214 before returning at step 216. If the resistance is less than the fault setting limit in step 206, then routine 200 proceeds to decision step 208 to determine whether the fault setting time has reached the fault setting time limit. If the fault setting timer exceeds the fault setting time limit, routine 200 sets a wet seat fault at step 212 and then returns at step 216. If the fault timer has not reached the fault setting time limit, then routine 200 increments the wet seat fault timer at step 210 and thereafter returns at step 216.

The wet seat fault setting routine 200 thereby sets the wet seat fault when certain conditions are met. In the disclosed embodiment, routine 200 sets the wet seat fault when two conditions, namely, the difference between the low and high frequency Q_{X} values exceeds a fault limit and the resistance value exceeds a fault setting limit resistance value, simultaneously for a fault setting time period determined by the fault timer, such as sixty (60) seconds according to one example. If either of the two conditions does not exist, the wet seat fault timer is cleared and the wet seat fault is not set.

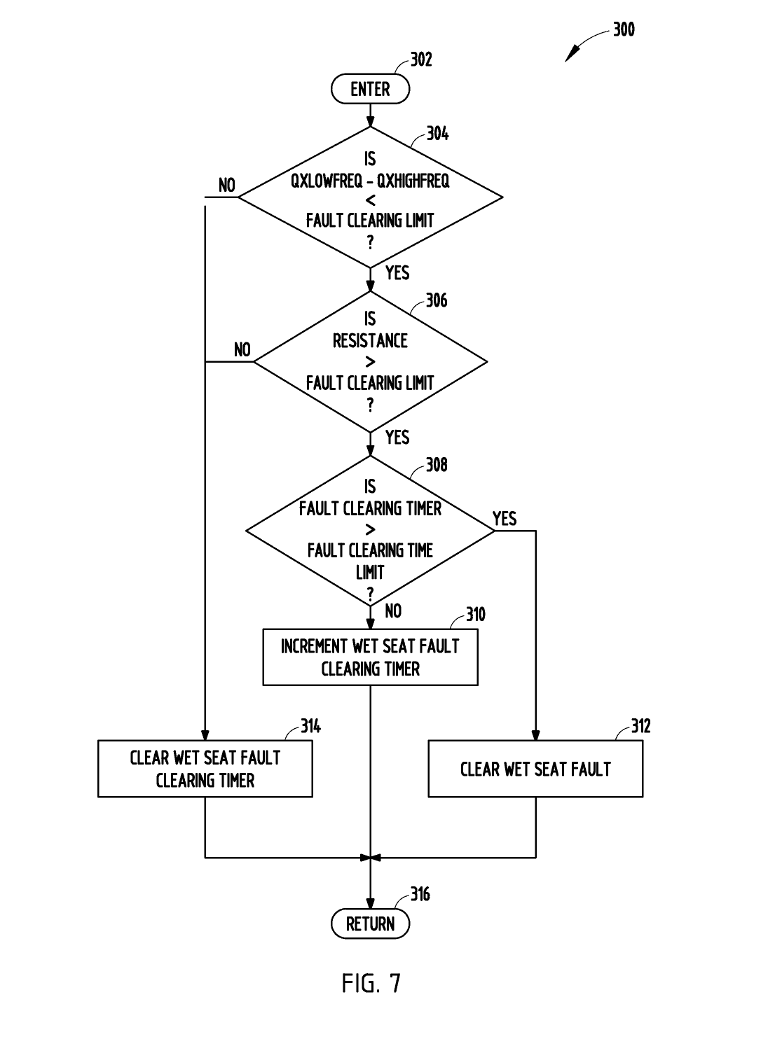

The wet seat fault clearing compensation routine 300 is illustrated in FIG. 7, according to one embodiment. Routine 300 begins at step 302 and proceeds to decision step 304 to determine if the difference between the low frequency Q_{X} value Q_{X}LowFreq and the high frequency Q_{X} value Q_{X}HighFreq is less than a fault clearing limit and, if not, proceeds to step 314 to clear the wet seat fault clearing timer before returning at step 316. If the difference exceeds the fault clearing limit, then routine 300 proceeds to decision step 306 to determine whether the resistance is greater than a fault clearing limit resistance value. If the resistance is not greater than the fault clearing limit resistance value, then routine 300 proceeds to clear the wet seat fault clearing timer at step 314 before returning at step 316. If the resistance is greater than the fault clearing limit resistance in step 306, then routine 300 proceeds to decision step 308 to determine whether the fault time has reached the fault clearing time limit. If the fault timer exceeds the fault clearing time limit, routine 300 clears a wet seat fault at step 312, and then returns at step 316. If the fault timer has not reached the fault clearing time limit, then routine 300 increments the wet seat fault clearing timer at step 310, and thereafter returns at step 316.

Once set, the wet seat fault remains set for repeated uses until cleared by the wet seat fault clearing routine 300 which clears the wet seat fault when certain conditions are met. In the disclosed embodiment, routine 300 clears the wet seat fault when the conditions, namely, the difference between the low and high frequency Q_{X} values is less than the fault clearing limit and the calculated resistance value exceeds the fault clearing limit resistance value, simultaneously for a time period determined by the fault clearing timer, such as thirty (30) seconds according to one example. If either of the two conditions does not exist, then wet seat fault timer is cleared and the wet seat fault is not cleared.

The fault setting limit and the fault clearing limit values may be different values. According to one embodiment, the fault setting limit is greater than the fault clearing limit such that hysteresis is provided in the range between the two limit values. The fault setting limit resistance and the fault clearing limit resistance values may be different values. According to one embodiment, the fault clearing limit resistance is greater than the fault setting limit resistance, such that hysteresis is provided in the range between the two resistance values.

For each wet seat fault setting and clearing cycle, various parameters are recorded in non-volatile memory of the ECU. The recorded parameters may include the following: the wet seat fault occurrence counter representing the number of times the wet seat fault has been set (including the current occurrence); the vehicle engine ignition cycle counter value in the ignition cycle when the wet seat fault is set; the differential Q_{X} (low frequency−high frequency) value when the wet seat fault is set; the calculated seat resistance value when the wet set fault is set; and the ignition cycle counter value in the ignition cycle when the wet seat fault is cleared. According to one embodiment, the occupant detection system 20 records the above parameters for a set number X of wet seat fault setting clearing cycles, such as six cycles in one example. In one embodiment, the X event records include the first X−1 wet seat fault occurrences and the most recent wet seat fault occurrence.

The occupant detection system 20 may adjust the threshold value Q_{X} used to determine occupancy based on a wet seat fault occurrences. Multiple wet and dry cycles in a vehicle seat caused by repeated spills of liquid and/or exposure to rain may create a load capacitance offset in the seat. To compensate for changes caused by repeated wet seat faults in a seat, a wet seat fault occurrence counter may be used as an input to a lookup table to adjust the threshold, according to one embodiment. One example of a lookup table for providing wet seat fault compensation values based on the wet seat fault occurrence counter is provided in Table I below:

TABLE I

| WSF Occurrence Counter | WSF Compensation |
|---|---|
| 0 | 0 |
| 1 | +10 |
| 2 | +15 |
| 3 | +20 |
| 4 | +25 |
| 5 | +25 |
| 6 | +25 |
| 7 | +25 |
| 8 | +25 |

In the above Table I, the wet seat fault (WSF) occurrence counter has counts that correspond to the wet seat fault compensation of the Q_{X} value. Each counter value has a compensation value that corresponds thereto. The compensation value is used to increase the threshold value Q_{X} by the amount of compensation that corresponds to the WSF occurrence counter. Thus, for example, a count value of six provides a compensation of +25 to the Q_{X} value, according to the example shown. Thus, the occupant detection system 20 compensates for wet conditions of the seat based on the wet seat fault occurrences.

Accordingly, the occupant detection system 20 advantageously compensates for wet seat conditions detected in the seat and the sensor. Thus, changes due to the presence of liquid may be taken into consideration and compensated to provide for accurate occupant detection.

It will be understood by those who practice the invention and those skilled in the art, that various modifications and improvements may be made to the invention without departing from the spirit of the disclosed concept. The scope of protection afforded is to be determined by the claims and by the breadth of interpretation allowed by law.

1. An occupant detection system comprising:
a capacitive sensor comprising an electrode arranged in a seat proximate to an expected location of an occupant for sensing an occupant presence proximate thereto, said capacitive sensor configured to provide an output indicative of the sensed occupant presence; and
occupant detection circuitry for processing the capacitive sensor output and determining a wet seat condition and generating a wet seat fault based on a determined wet seat condition, wherein the occupant detection circuitry further detects a state of occupancy of the seat based on the capacitive sensor output and the wet seat fault.

2. The occupant detection system as defined in claim 1, wherein the occupant detection circuitry determines one or more wet seat fault conditions and generates a compensation value based on the wet seat fault conditions, wherein the compensation value is used to adjust one of the capacitive sensor output and a threshold value to compensate for the wet seat condition.

3. The occupant detection system as defined in claim 2, wherein the compensation value is acquired from a lookup table having a plurality of wet seat fault conditions and corresponding compensation values.

4. The occupant detection system as defined in claim 1, wherein the occupant detection circuitry senses a wet seat fault based on detected resistance and a difference in the capacitive sensor output at a first frequency and a second frequency.

5. The occupant detection system as defined in claim 4, wherein the wet seat fault is set when the resistance is less than a threshold resistance and the difference is greater than a threshold limit for a minimum time period.

6. The occupant detection system as defined in claim 1, wherein the occupant detection circuitry classifies the occupant as one of an adult and a child.

7. The occupant detection system as defined in claim 1, wherein the capacitive sensor comprises an electrically conductive mat disposed on the seat.

8. The occupant detection system as defined in claim 1, wherein the capacitive sensor comprises a signal generator for applying an alternating current signal to the electrode and a voltage detector for receiving a voltage signal, wherein the voltage signal is compared to a voltage threshold to generate the capacitive sensing output.

9. The occupant detection system as defined in claim 1, wherein the seat comprises a vehicle seat.

10. A method of detecting an occupant in a seat, said method comprising the steps of:
applying an alternating current signal to an electrode arranged in a seat proximate to an expected location of an occupant for generating an electric field at the expected location;
detecting a voltage response to the electric field;
generating an output based on the voltage response indicative of a characteristic of an occupant;
detecting a wet seat condition;
generating a wet seat fault based on the detected wet seat condition; and
detecting a state of occupancy of the seat based on the output and the wet seat fault.

11. The method as defined in claim 10 further comprising the steps of determining one or more wet seat fault conditions and generating a compensation value based on the one or more wet seat fault conditions, wherein the compensation value is used to adjust one of the capacitive sensor output and a threshold value to compensate for the wet seat condition.

12. The method as defined in claim 11, wherein the compensation value is acquired from a lookup table having a plurality of wet seat fault conditions and corresponding compensation values.

13. The method as defined in claim 10, wherein the step of generating a wet seat fault comprises sensing a wet seat fault based on detected resistance and a difference in the capacitive sensor output at a first frequency and a second frequency.

14. The method as defined in claim 13, wherein the wet seat fault is set when the resistance is less than a threshold resistance and the difference is greater than a threshold limit for a minimum time period.

15. The method as defined in claim 10, wherein the characteristic of an occupant is one of an adult and child.

16. The method as defined in claim 10, wherein the electrode provides capacitive sensing.

17. The method as defined in claim 10, wherein the seat is a vehicle seat.

18. The method as defined in claim 10, wherein the first output is generated based on a capacitive threshold.
